(19) United States
(12) Patent Application Publication
(10) Pub. No.: US 2026/0157199 A1
(43) Pub. Date: Jun. 4, 2026

(54) SEMICONDUCTOR PACKAGE

(71) Applicant: SAMSUNG ELECTRONICS CO., LTD., Suwon-si (KR)

(72) Inventors: HYEONJEONG HWANG, Suwon-si (KR); JUNGHOON KANG, Suwon-si (KR)

(73) Assignee: SAMSUNG ELECTRONICS CO., LTD., Suwon-si (KR)

(21) Appl. No.: 19/236,479

(22) Filed: Jun. 12, 2025

(30) Foreign Application Priority Data
Nov. 29, 2024 (KR) 10-2024-0174962

(51) Int. Cl. H10W 70/65; H10W 70/63; H10W 70/692; H10W 74/10; H10W 90/00

(52) U.S. Cl. CPC H10W 70/65; H10W 70/635; H10W 70/692; H10W 74/111; H10W 90/00

(57) ABSTRACT

Provided is a semiconductor package including a first substrate, a molding layer on the first substrate, the molding layer including a first semiconductor chip and a capacitor spaced apart from the first semiconductor chip in a first direction, a core layer on the molding layer, and a second substrate on the core layer, wherein the second substrate includes an upper conductive pad, wherein the core layer includes an inductor pattern penetrating the core layer in a third direction intersecting the first direction, wherein the inductor pattern is connected to the capacitor by a connection conductive pad, and wherein a top surface of the inductor pattern is in contact with the upper conductive pad.

### CROSS-REFERENCE TO RELATED APPLICATIONS

This application claims priority to Korean Patent Application No. 10-2024-0174962 filed on November 29, 2024, in the Korean Intellectual Property Office, the disclosure of which is incorporated by reference herein in its entirety.

### BACKGROUND

Embodiments of the present disclosure relate to a semiconductor package, and more particularly, to a semiconductor package having a noise removal filter.

Semiconductor memory devices includes volatile memory devices, which lose data stored therein at power-off, including a static random access memory (SRAM), a dynamic RAM (DRAM), and a synchronous DRAM (SDRAM), and nonvolatile memory devices, which retain data stored therein even at power-off, including a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), and a ferroelectric RAM (FRAM).

In general, a semiconductor device transmits and receives signals to and from an external apparatus (e.g., a memory controller) through a pad. However, with recent increases in integration and communication speed of the semiconductor device, noise is generated during signal transmission/reception through the pad. This is because reflected waves generated during signal transmission increases during high-speed operation, and these reflected waves flow into external devices or semiconductor devices through the pad. These problems worsen the reliability of semiconductor devices.

### SUMMARY

One or more embodiments provide a semiconductor package with improved operation reliability.

One or more embodiments also provide a semiconductor package with improved miniaturization.

One or more embodiments also provide a semiconductor package with improved electrical characteristics.

According to an aspect of one or more embodiments, there is provided a semiconductor package including a first substrate, a molding layer on the first substrate, the molding layer including a first semiconductor chip and a capacitor spaced apart from the first semiconductor chip in a first direction, a core layer on the molding layer, and a second substrate on the core layer, wherein the second substrate includes an upper conductive pad, wherein the core layer includes an inductor pattern penetrating the core layer in a third direction intersecting the first direction, wherein the inductor pattern is connected to the capacitor by a connection conductive pad, and wherein a top surface of the inductor pattern is in contact with the upper conductive pad.

According to another aspect of one or more embodiments, there is provided a semiconductor package including a first substrate including a lower conductive pad, a molding layer on the first substrate, the molding layer including a first semiconductor chip and a capacitor spaced apart from the first semiconductor chip in a first direction, a core layer on the molding layer, and a second substrate on the core layer, wherein the second substrate includes an upper conductive pad, wherein the core layer includes an inductor pattern penetrating the core layer in a third direction intersecting the first direction, wherein a top surface of the inductor pattern is in contact with the upper conductive pad, and wherein a bottom surface of the capacitor is in contact with the lower conductive pad.

According to still another aspect of one or more embodiments, there is provided a semiconductor package including a first substrate, a molding layer on the first substrate, the molding layer including a first semiconductor chip and a capacitor spaced apart from the first semiconductor chip in a first direction, a core layer on the molding layer, and a second substrate on the core layer, wherein the second substrate includes an upper conductive pad, wherein the core layer includes a plurality of inductor patterns penetrating the core layer in a third direction intersecting the first direction, wherein the molding layer includes a conductive pad on the plurality of inductor patterns, wherein the conductive pad includes a connection conductive pad interposed between at least one of the plurality of inductor patterns and the capacitor, wherein top surfaces of the plurality of inductor patterns are connected to each other by the upper conductive pad, and wherein the bottom surfaces of the plurality of inductor patterns are connected to each other by the conductive pad.

### BRIEF DESCRIPTION OF DRAWINGS

Embodiments will be more clearly understood from the following detailed description taken in conjunction with the accompanying drawings in which:

FIG. 1 is a plan view of a semiconductor package according to one or more embodiments;

FIG. 2 is a cross-sectional view along line X-X’ of FIG. 1 for illustrating a semiconductor package according to one or more embodiments;

FIG. 3A is an enlarged view of region ‘M’ according to FIG. 2;

FIG. 3B is an enlarged view of region ‘M’ according to FIG. 2;

FIG. 4A is a plan view along line A-A’ of FIG. 2, and is a plan view for illustrating a plan shape of an upper redistribution pattern according to one or more embodiments;

FIG. 4B is a plan view along line B-B’ of FIG. 2, and is a plan view for illustrating a plan shape of a lower redistribution pattern according to one or more embodiments;

FIG. 5 is a perspective view for illustrating an inductor according to one or more embodiments; and

FIGS. 6, 7, 8, 9, 10, and 11 are cross-sectional views for illustrating a method for manufacturing a semiconductor package according to embodiments of the inventive concept.

### DETAILED DESCRIPTION

Hereinafter, embodiments are described in detail with reference to the accompanying drawings. The same reference numerals denote the same elements in the drawings, and redundant descriptions on the same elements are omitted.

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

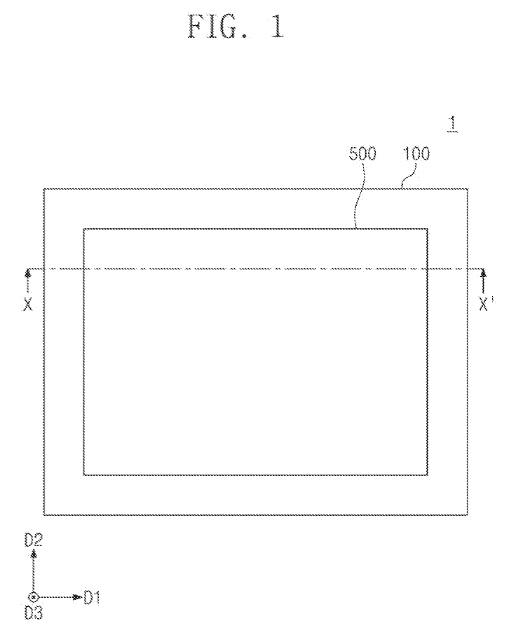

FIG. 1 is a plan view of a semiconductor package according to one or more embodiments.

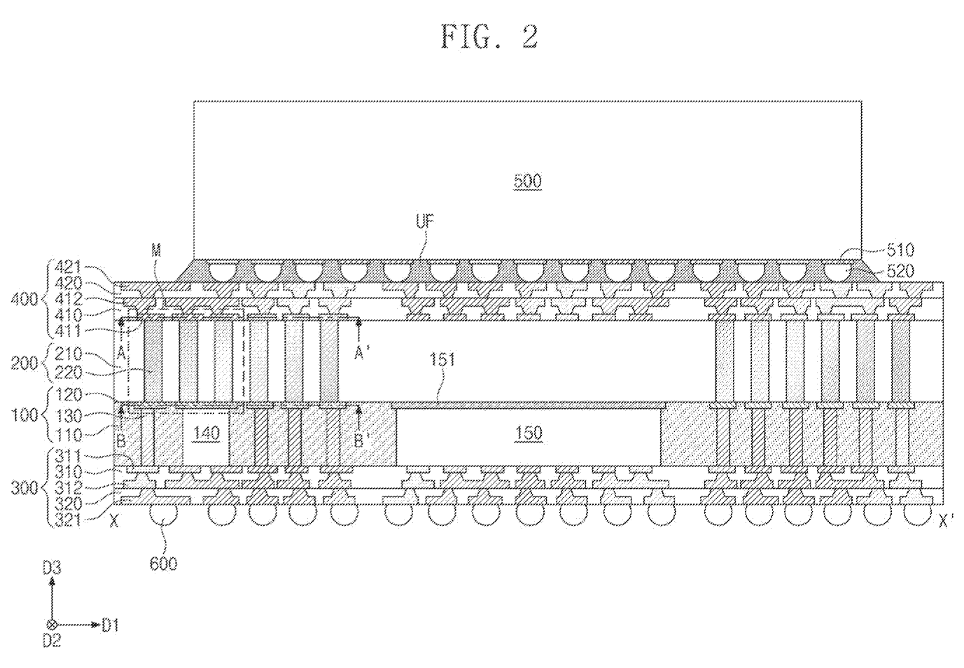

FIG. 2 is a cross-sectional view along line X-X’ of FIG. 1 for illustrating a semiconductor package according to one or more embodiments.

Referring to FIGS. 1 and 2, a semiconductor package 1 according to one or more embodiments may include a first package substrate 300, a molding layer 100, a core layer 200, a second package substrate 400, a second semiconductor chip 500, and external terminals 600.

In the present disclosure, a first direction D1 is defined as a direction parallel to a top surface of the first package substrate 300. A second direction D2 is defined as a direction parallel to the top surface of the first package substrate 300 and perpendicular to the first direction D1. A third direction D3 is defined as a direction perpendicular to the top surface of the first package substrate 300.

The first package substrate 300 may be a redistribution substrate. For example, the first package substrate 300 may include at least two or more redistribution layers that are mutually stacked. In the present disclosure, the redistribution layer may be a wiring layer formed by patterning one insulating material layer and one conductive material layer, respectively. For example, the conductive patterns in one redistribution layer may be horizontally extending wirings and may not vertically overlap each other.

The first package substrate 300 may include a first lower insulating pattern 310 and a second lower insulating pattern 320 that are stacked. The first lower insulating pattern 310 may be provided on the second lower insulating pattern 320.

A first lower conductive pad 311 and a first lower wiring pattern 312 may be provided in the first lower insulating pattern 310. The first lower conductive pad 311 may be provided on the first lower wiring pattern 312. The first lower wiring pattern 312 may be electrically and/or physically connected to the first lower conductive pad 311. Hereinafter, electrically and/or physically connected may include directly or indirectly connected.

A second lower wiring pattern 321 may be provided in the second lower insulating pattern 320. A top surface of the second lower wiring pattern 321 may be in contact with a bottom surface of the first lower wiring pattern 312. The second lower wiring pattern 321 may be electrically and/or physically connected to the first lower wiring pattern 312.

Each of the first and second lower wiring patterns 312 and 321 may include a via portion and a wiring portion integrally connected to each other. The wiring portion may be a pattern for horizontal connection in the first package substrate 300. The via portion may be a portion that vertically connects the wiring portions in the first and second lower insulating patterns 310 and 320. For example, the via portion of the first lower wiring pattern 312 may vertically connect the first lower conductive pad 311 and the wiring portion of the first lower wiring pattern 312. The via portion of the second lower wiring pattern 321 may vertically connect the wiring portion of the first lower wiring pattern 312 and the wiring portion of the second lower wiring pattern 321.

The via portion may be provided on the wiring portion. The via portion and the wiring portion may be integrally formed and connected without an interface. A width of the wiring portion may be greater than a width of the via portion in the first direction D1 and/or second direction D2. As a result, the first and second lower wiring patterns 312 and 321 may have a cross-section of an inverted ‘T’ shape.

As another example, additional lower insulating patterns may be disposed on the first and second lower insulating patterns 310 and 320. Each of the described stacked lower insulating patterns may include lower wiring patterns, and adjacent lower wiring patterns may be electrically and/or physically connected to each other.

The first lower insulating pattern 310 and the second lower insulating pattern 320 may include an insulating polymer material, and the first and second lower wiring patterns 312 and 321 may include a metal (e.g., copper). The first and second lower wiring patterns 312 and 321 may include a conductive material.

The first and second lower wiring patterns 312 and 321 may redistribute a first semiconductor chip 150 mounted on the first package substrate 300.

Although FIG. 2 illustrates that the via portions of the first and second lower wiring patterns 312 and 321 protrude onto the wiring portion, embodiments are not limited thereto. The wiring portions of each of the first and second lower wiring patterns 312 and 321 may be provided on the via portions, respectively. The first and second lower wiring patterns 312 and 321 may have a ‘T’ shape.

A barrier layer may be interposed between the first lower insulating pattern 310 and the first lower wiring pattern 312 and between the first lower insulating pattern 310 and the first lower conductive pad 311. The barrier layer may conformally be provided on and cover a side surface and a bottom surface of each of the first lower wiring pattern 312 and the first lower conductive pad 311. A thickness of the barrier layer may be 50 Å to 1000 Å. The barrier layer may include a metal such as, for example, titanium (Ti) and tantalum (Ta), or may include a metal nitride such as titanium nitride (TiN) and tantalum nitride (TaN).

The barrier layer may also be interposed between the second lower insulating pattern 320 and the second lower wiring pattern 321. The barrier layer may conformally be provided on and cover a side surface and a bottom surface of the second lower wiring pattern 321.

The external terminals 600 may be disposed below the first package substrate 300. For example, the external terminals 600 may be disposed on a bottom surface of the second lower wiring patterns 321 disposed on a bottom surface of the first package substrate 300. The external terminals 600 may include solder balls or solder bumps, and the semiconductor package may be provided in a form of a ball grid array (BGA), a fine ball-grid array (FBGA), or a land grid array (LGA), depending on the type and arrangement of the external terminals 600.

The molding layer 100 may be provided on the first package substrate 300. The molding layer 100 may include a first molding layer 110, a conductive pad 120, a vertical conductive via 130, a capacitor 140, and a first semiconductor chip 150. The conductive pad 120, the vertical conductive via 130, the capacitor 140, and the first semiconductor chip 150 may be provided in the first molding layer 110. The first molding layer 110 may include an insulating material, and the insulating material may include a material such as, for example, an epoxy molding compound, or an adhesive material.

The conductive pad 120 may be provided on an upper portion of the molding layer 100 and may be connected to an inductor pattern 220 to be described later. The conductive pad 120 may be interposed between the inductor pattern 220 to be described later and the vertical conductive via 130. The inductor pattern 220 and the vertical conductive via 130 may be connected by the conductive pad 120.

The vertical conductive via 130 may extend vertically in the third direction D3 in the first molding layer 110. A top surface of the vertical conductive via 130 may be in contact with a bottom surface of the conductive pad 120. The vertical conductive via 130 may include a conductive material. For example, the vertical conductive via 130 may include copper (Cu). The vertical conductive via 130 may connect the inductor pattern 220 and the wirings of the first package substrate 300. In detail, the vertical conductive via 130 may connect the inductor pattern 220 and the lower conductive pad 311.

The capacitor 140 may be spaced apart from the vertical conductive via 130 in the first direction D1. The capacitor 140 may include facing conductive plates and a dielectric interposed therebetween. The capacitor 140 may filter a wireless signal and may constitute an LC circuit with an inductor. A conductive pad 120 may be provided on the capacitor 140. A bottom surface of the capacitor 140 may be in contact with the wirings of the first package substrate 300. For example, the bottom surface of the capacitor 140 may be in contact with and connected to the first lower conductive pad 311 of the first package substrate 300.

The first semiconductor chip 150 may be disposed on a top surface of the first package substrate 300. For example, the first semiconductor chip 150 may be a radio frequency (RF) chip. The first semiconductor chip 150 may be a semiconductor chip that transmits and/or receives or processes a wireless signal. The first semiconductor chip 150 may be provided at a central portion of the molding layer 100. The first semiconductor chip 150 may be spaced apart from the vertical conductive via 130 and the capacitor 140 in the first direction D1. For example, the vertical conductive via 130 and the capacitor 140 may be disposed at an edge portion of the first molding layer 110, and the first semiconductor chip 150 may be disposed at a central portion of the first molding layer 110. A bottom surface of the first semiconductor chip 150 may be disposed at substantially the same level as a bottom surface of the vertical conductive via 130 and a bottom surface of the capacitor 140 in the third direction D3.

A bottom surface of the first semiconductor chip 150 may be in contact with the wirings of the first package substrate 300. For example, the bottom surface of the first semiconductor chip 150 may be connected to the first lower conductive pad 311 of the first package substrate 300.

An adhesive layer 151 may be provided on a top surface of the first semiconductor chip 150. The adhesive layer 151 may include an adhesive material. For example, the adhesive layer 151 may include an adhesive tape. By the adhesive layer 151, the first semiconductor chip 150 and the core layer 200 may be more stably adhered to each other.

The core layer 200 may be provided on the molding layer 100. The core layer 200 may include a core substrate 210 and an inductor pattern 220 in the core substrate 210. The core substrate 210 may include, for example, glass. For example, the core substrate 210 may be a glass substrate. The adhesive layer 151 may be interposed between a bottom surface of the core layer 200 and a top surface of the first semiconductor chip 150.

The core layer 200 may include a plurality of inductor patterns 220. The inductor patterns 220 may vertically penetrate the core substrate 210 in the third direction D3. The inductor pattern 220 may have, for example, a pillar shape. For example, the inductor pattern 220 may have a cylindrical shape.

The second package substrate 400 may be provided on the core layer 200. The second package substrate 400 may be substantially the same as the first package substrate 300. The second package substrate 400 may be a redistribution substrate. For example, the second package substrate 400 may include at least two or more redistribution layers that are mutually stacked.

The second package substrate 400 may include a first upper insulating pattern 410 and a second upper insulating pattern 420 that are stacked. The second upper insulating pattern 420 may be provided on the first upper insulating pattern 410.

A first upper conductive pad 411 and a first upper wiring pattern 412 may be provided in the first upper insulating pattern 410. The first upper wiring pattern 412 may be provided on the first upper conductive pad 411. The first upper conductive pad 411 may be electrically and/or physically connected to the first upper wiring pattern 412.

A second upper wiring pattern 421 may be provided in the second upper insulating pattern 420. A bottom surface of the second upper wiring pattern 421 may be in contact with a top surface of the first upper wiring pattern 412. The second upper wiring pattern 421 may be electrically and/or physically connected to the first upper wiring pattern 412.

Each of the first and second upper wiring patterns 412 and 421 may include a via portion and a wiring portion integrally connected to each other. The wiring portion may be a pattern for horizontal connection in the second package substrate 400. The via portion may be a portion that vertically connects the wiring portions in the first and second upper insulating patterns 410 and 420. For example, the via portion of the first upper wiring pattern 412 may vertically connect the first upper conductive pad 411 and the wiring portion of the first upper wiring pattern 412. The via portion of the second upper wiring pattern 421 may vertically connect the wiring portion of the first upper wiring pattern 412 and the wiring portion of the second upper wiring pattern 421.

The wiring portions of each of the first and second upper wiring patterns 412 and 421 may be provided on the via portions, respectively. The first and second upper wiring patterns 412 and 421 may have a ‘T’ shape.

As another example, upper insulating patterns may be additionally disposed on the first and second upper wiring patterns 412 and 421. Each of the stacked upper insulating patterns may include upper wiring patterns, and other upper wiring patterns adjacent to each other may be electrically and/or physically connected.

The first upper insulating pattern 410 and the second upper insulating pattern 420 may include an insulating polymer material, and the first and second upper wiring patterns 412 and 421 may include a metal (e.g., copper). The first and second upper wiring patterns 412 and 421 may include a conductive material.

In FIG. 2, the via portions of the first and second upper wiring patterns 412 and 421 are illustrated as protruding below the wiring portions, but embodiments are not limited thereto. The wiring portions of each of the first and second upper wiring patterns 412 and 421 may be provided below each via portion. Accordingly, the first and second upper wiring patterns 412 and 421 may have an inverted ‘T’ shape.

A second semiconductor chip 500 may be provided on the second package substrate 400. The second semiconductor chip 500 may be a different type of semiconductor chip from the first semiconductor chip 150. The second semiconductor chip 500 may be, for example, a logic chip or a memory chip. The second semiconductor chip 500 may be, for example, one of a central processing unit (CPU), a graphics processing unit (GPU), an application specific integrated circuit (ASIC), a dynamic random access memory (DRAM), an static random access memory (SRAM), and a NAND FLASH. The second semiconductor chip 500 may include a plurality of chip pads 510 provided on a lower surface thereof. The chip pads 510 may be electrically and/or physically connected to an integrated circuit of the second semiconductor chip 500.

Connection terminals 520 may be disposed between the second package substrate 400 and the second semiconductor chip 500. For example, the connection terminals 520 may be interposed between the second upper wiring pattern 421 and the chip pads 510 and may be in contact with the second upper wiring pattern 421 and the chip pads 510. The second semiconductor chip 500 may be electrically and/or physically connected to the second package substrate 400 through the connection terminals 520. The connection terminals 520 may be an alloy including at least one of, for example, tin (Sn), silver (Ag), copper (Cu), nickel (Ni), bismuth (Bi), indium (In), antimony (Sb), or cerium (Ce).

An underfill pattern UF may be provided between the second package substrate 400 and the second semiconductor chip 500. The underfill pattern UF may include, for example, an epoxy resin composition. The underfill pattern UF may fill a space between the connection terminals 520.

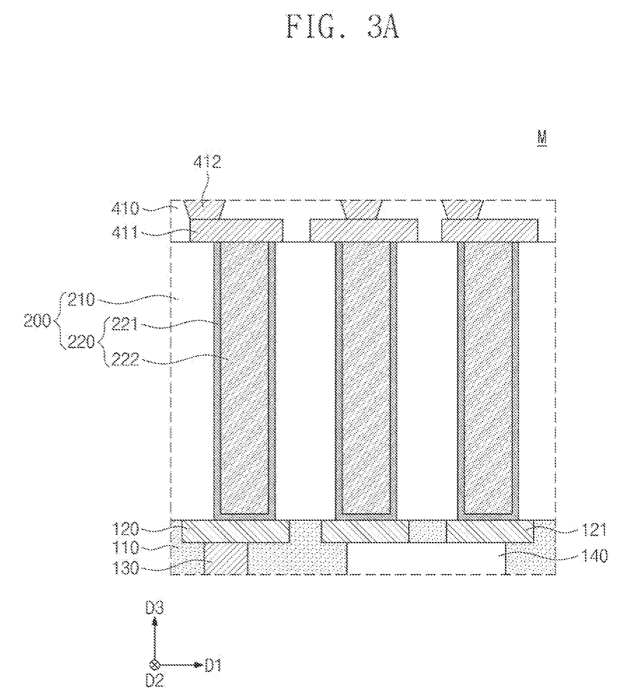

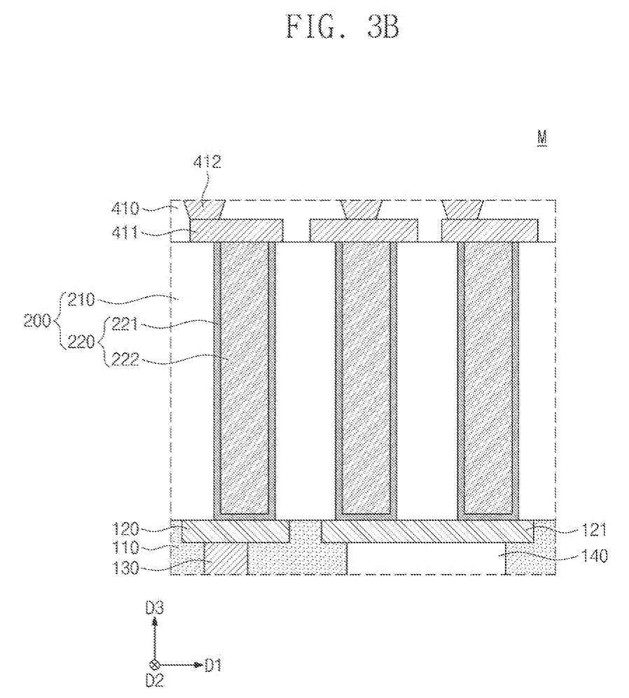

FIG. 3A is an enlarged view of region ‘M’ according to one embodiment of FIG. 2. FIG. 3B is an enlarged view of region ‘M’ according to another embodiment of FIG. 2. Referring to FIGS. 3A and 3B, the inductor pattern 220 will be described in more detail.

Referring to FIG. 3A, the core layer 200 may include a plurality of inductor patterns 220 that vertically penetrate the core layer 200 in the third direction D3. Wirings of the molding layer 100 may be connected to wirings of the second package substrate 400 each other, through the inductor pattern 220. For example, the inductor pattern 220 may be interposed between the conductive pad 120 and the first upper conductive pad 411. A bottom surface of the inductor pattern 220 may be in contact with a top surface of the conductive pad 120 of the molding layer 100. A top surface of the inductor pattern 220 may be in contact with a bottom surface of the first upper conductive pad 411 of the second package substrate 400. The conductive pad 120 may be connected to the first upper conductive pad 411 by the inductor pattern 220.

A capacitor 140 may be disposed below the inductor pattern 220. The inductor pattern 220 may be vertically overlapped with the capacitor 140. The conductive pads 120 may include a connection conductive pad 121 interposed between the inductor pattern 220 and the capacitor 140. For example, the connection conductive pad 121 may be provided between the bottom surface of the inductor pattern 220 and the top surface of the capacitor 140. The inductor pattern 220 and the capacitor 140 may be electrically and/or physically connected by the connection conductive pad 121. The capacitor 140 may be connected by a plurality of inductor patterns 220 and a plurality of connection conductive pads 121.

As another example, referring to FIG. 3B, the capacitor 140 may be connected to a plurality of inductor patterns 220 by a single connection conductive pad 121. In this example, the connection conductive pad 121 may be in contact with the bottom surfaces of the plurality of inductor patterns 220. A width of the single connection conductive pad 121 may be greater than a width of the conductive pads 120 in the first direction D1 and/or second direction D2 as illustrated in FIG. 3A.

The inductor pattern 220 may include an inductor barrier pattern 221 and an inductor conductive pattern 222 on the inductor barrier pattern 221. The inductor barrier pattern 221 may be provided on and cover sidewalls and a bottom surface of the inductor conductive pattern 222. The inductor barrier pattern 221 may include a metal layer/metal nitride layer. The metal layer may include at least one of, for example, titanium (Ti), tantalum (Ta), tungsten (W), nickel (Ni), cobalt (Co), and platinum (Pt). The metal nitride layer may include at least one of, for example, a titanium nitride layer (TiN), a tantalum nitride layer (TaN), a tungsten nitride layer (WN), a nickel nitride layer (NiN), a cobalt nitride layer (CoN), and a platinum nitride layer (PtN).

The inductor conductive pattern 222 may include a conductive material. For example, the inductor conductive pattern 222 may include at least one metal of aluminum (Al), copper (Cu), tungsten (W), molybdenum (Mb), and cobalt (Co).

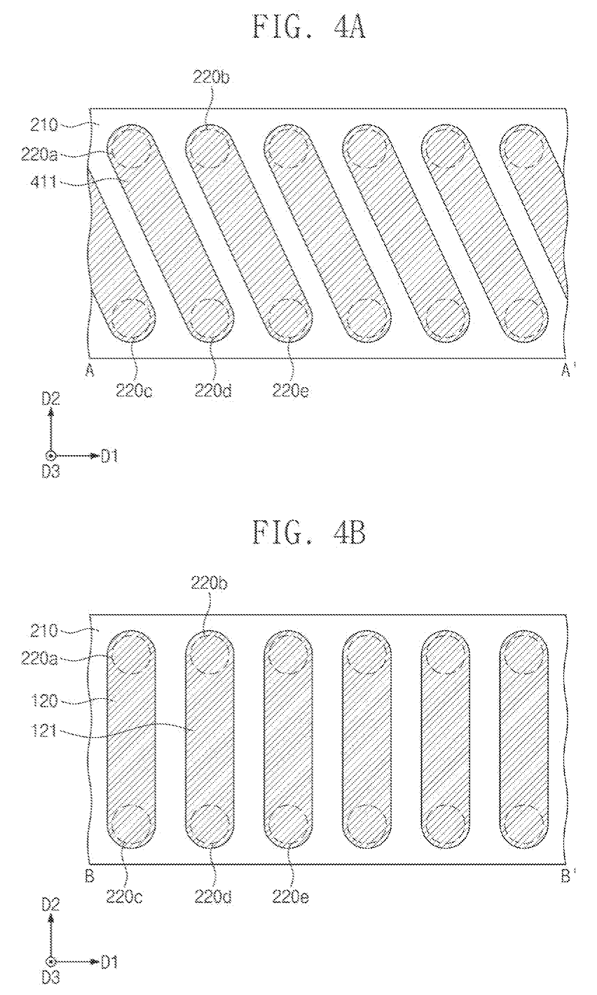

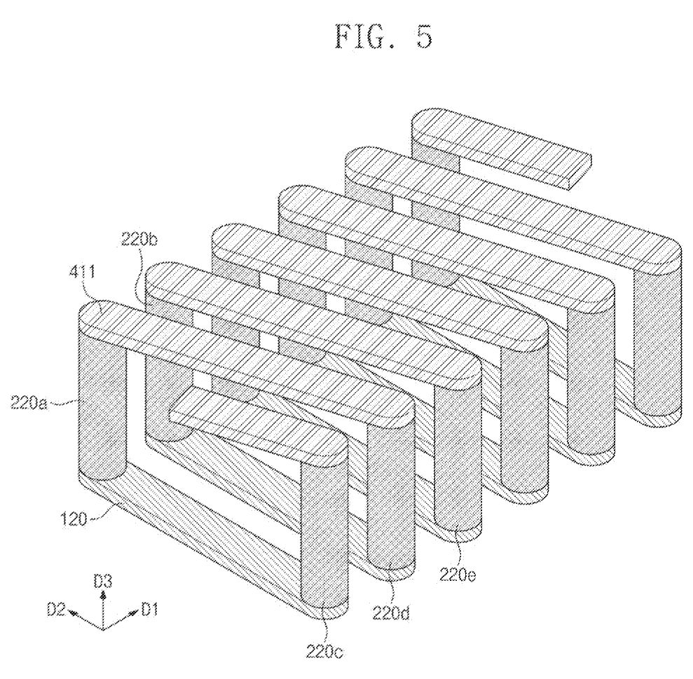

FIG. 4A is a plan view along line A-A’ of FIG. 2, and is a plan view for illustrating a plan shape of an upper redistribution pattern. FIG. 4B is a plan view along line B-B’ of FIG. 2, and is a plan view for illustrating a plan shape of a lower redistribution pattern. FIG. 5 is a perspective view for illustrating an inductor according to one or more embodiments. Referring to FIGS. 4A, 4B, and 5, the inductor pattern 220, the first upper conductive pad 411, and the conductive pad 120 will be described in more detail.

Referring to FIGS. 4A and 5, a plurality of inductor patterns 220 may be arranged in a core substrate 210. The inductor patterns 220 may be disposed spaced apart from each other in the first direction D1 and the second direction D2. A spacing between the inductor patterns 220 adjacent to each other in the first direction D1 may be less than a spacing between the inductor patterns 220 adjacent to each other in the second direction D2. However, embodiments are not limited thereto, and the inductor patterns 220 may be disposed at various positions as needed.

For example, the inductor patterns 220 may include a first inductor pattern 220a and a second inductor pattern 220b adjacent to each other in the first direction D1. A third inductor pattern 220c may be spaced apart from the first inductor pattern 220a in the second direction D2. A fourth inductor pattern 220d may be spaced apart from the third inductor pattern 220c in the first direction D1, and a fifth inductor pattern 220e may be spaced apart from the fourth inductor pattern 220d in the first direction D1. In this case, the first inductor pattern 220a and the third inductor pattern 220c may be aligned in the second direction D2. Similarly, the second inductor pattern 220b and the fourth inductor pattern 220d may be aligned in the second direction D2.

Accordingly, the fourth inductor pattern 220d may be spaced apart from the first inductor pattern 220a in the first direction D1 and the second direction D2. The fourth inductor pattern 220d may be offset in the first direction D1 with respect to the first inductor pattern 220a. The fifth inductor pattern 220e may be spaced apart from the second inductor pattern 220b in the first direction D1 and the second direction D2. The fifth inductor pattern 220e may be offset in the first direction D1 with respect to the second inductor pattern 220b.

A plurality of first upper conductive pads 411 may be provided on the inductor patterns 220. The first upper conductive pads 411 may have a bar shape that extends at an acute angle with respect to each of the first direction D1 and the second direction D2. The first upper conductive pads 411 may extend obliquely.

The first upper conductive pads 411 may connect two or more inductor patterns 220. The first upper conductive pads 411 may connect two inductor patterns 220 that are spaced apart in the first direction D1 and the second direction D2. For example, the first upper conductive pad 411 may connect the first inductor pattern 220a and the fourth inductor pattern 220d. The first upper conductive pad 411 may connect the second inductor pattern 220b and the fifth inductor pattern 220e.

One end of the first upper conductive pad 411 may be in contact with a top surface of the first inductor pattern 220a, and the other end of the first upper conductive pad 411 may be in contact with a top surface of the fourth inductor pattern 220d. One end of the first upper conductive pad 411 may be in contact with a top surface of the second inductor pattern 220b, and the other end of the first upper conductive pad 411 may be in contact with a top surface of the fifth inductor pattern 220e.

Referring to FIGS. 4B and 5, conductive pads 120 may be provided below the inductor patterns 220. The conductive pads 120 may have a bar shape extending in the second direction D2.

The conductive pads 120 may connect two or more inductor patterns 220. The conductive pads 120 may connect two inductor patterns 220 that are spaced apart and aligned in the second direction D2. For example, the conductive pad 120 may connect the first inductor pattern 220a and the third inductor pattern 220c. The conductive pad 120 may connect the second inductor pattern 220b and the fourth inductor pattern 220d.

One end of the conductive pad 120 may be in contact with a bottom surface of the first inductor pattern 220a, and the other end of the conductive pad 120 may be in contact with a bottom surface of the third inductor pattern 220c. One end of the conductive pad 120 may be in contact with a bottom surface of the second inductor pattern 220b, and the other end of the conductive pad 120 may be in contact with a bottom surface of the fourth inductor pattern 220d.

However, embodiments are not limited thereto, and the first upper conductive pads 411 may be disposed similar to the conductive pads 120 of FIG. 4B, or, the conductive pads 120 may be disposed similar to the first upper conductive pads 411 of FIG. 4A.

Referring to FIG. 5, the inductor patterns 220 in the core layer 200 may be connected to the first upper conductive pads 411 and the conductive pads 120, thereby forming a coil shape. As a result, the inductor patterns 220, the first upper conductive pads 411, and the conductive pads 120 may operate as an inductor. For example, the inductor may be a passive element that forms a magnetic field when current flows, and a change in the magnetic field induces a current. All of the inductor patterns 220, the first upper conductive pads 411, and the conductive pads 120 may include a conductive material, and the inductor patterns 220, the first upper conductive pads 411, and the conductive pads 120 may be integrally connected to form a coil shape, thereby operating as an inductor.

Referring again to FIG. 2 and FIG. 5, an inductor and a capacitor connected to each other by a connection conductive pad 121 may constitute an LC circuit. The LC circuit may cause a resonance phenomenon when electromagnetic energy is periodically exchanged between the inductor and the capacitor. Accordingly, the LC circuit may filter a signal in a specific frequency band, operate as an oscillator, adjust a frequency, or store energy.

According to one or more embodiments, it is possible to provide the inductor patterns 220 that extend vertically in the core layer 200. The inductor patterns 220, the first upper conductive pads 411, and the conductive pads 120 may be connected to each other to integrally form the coil shape, thereby operating as the inductor. The inductors may be connected to the capacitors provided therebelow to form an LC circuit. This allows the first semiconductor chip 150 to filter wireless signals received or transmitted, or to remove noise from wireless signals.

In addition, as the core layer 200 includes glass, frequency loss of wireless signals (particularly, loss of high-frequency signals) may be minimized. Furthermore, as the inductor pattern 220 is used to form the inductor, an additional process for inserting the inductor may be not required, thereby reducing costs. As a result, electrical characteristics and reliability of the semiconductor package according to embodiments may be improved.

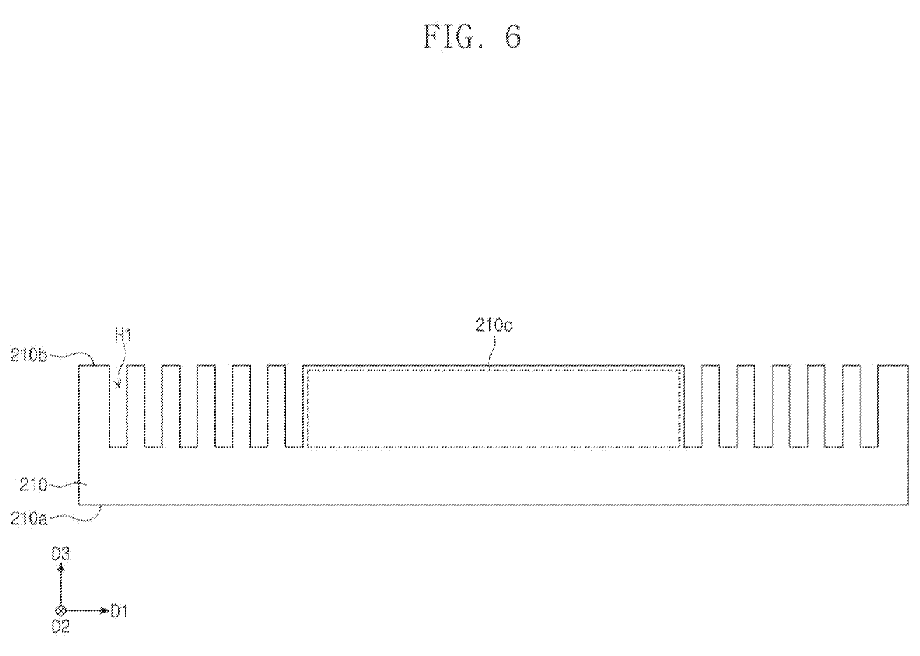

FIGS. 6, 7, 8, 9, 10, and 11 are cross-sectional views illustrating a method of manufacturing a semiconductor package according to one or more embodiments. FIGS. 6, 7, 8, 9, 10, and 11 are cross-sectional views along line X-X’ of FIG. 1.

Referring to FIG. 6, a core substrate 210 may be provided. The core substrate 210 may be, for example, a glass substrate. The core substrate 210 may include a first surface 210a and a second surface 210b facing each other. The first surface 210a may be substantially the same surface as a bottom surface of the core substrate 210. The second surface 210b may be substantially the same surface as a top surface of the core substrate 210.

A plurality of via holes H1 may be formed in the core substrate 210. Forming the via holes H1 may include emitting a laser onto the second surface 210b of the core substrate 210 to etch a portion of the core substrate 210, performing a wet etch process. The via holes H1 may not penetrate the core substrate 210.

The via holes H1 may be formed only on a portion of the core substrate 210. For example, the via holes H1 may not be formed in a central portion 210c of the core substrate 210, but may be formed only in edge portions disposed on both sides of the central portion 210c. This is because, in a subsequent manufacturing process, the first semiconductor chip 150 may be mounted below the central portion 210c of the core substrate 210.

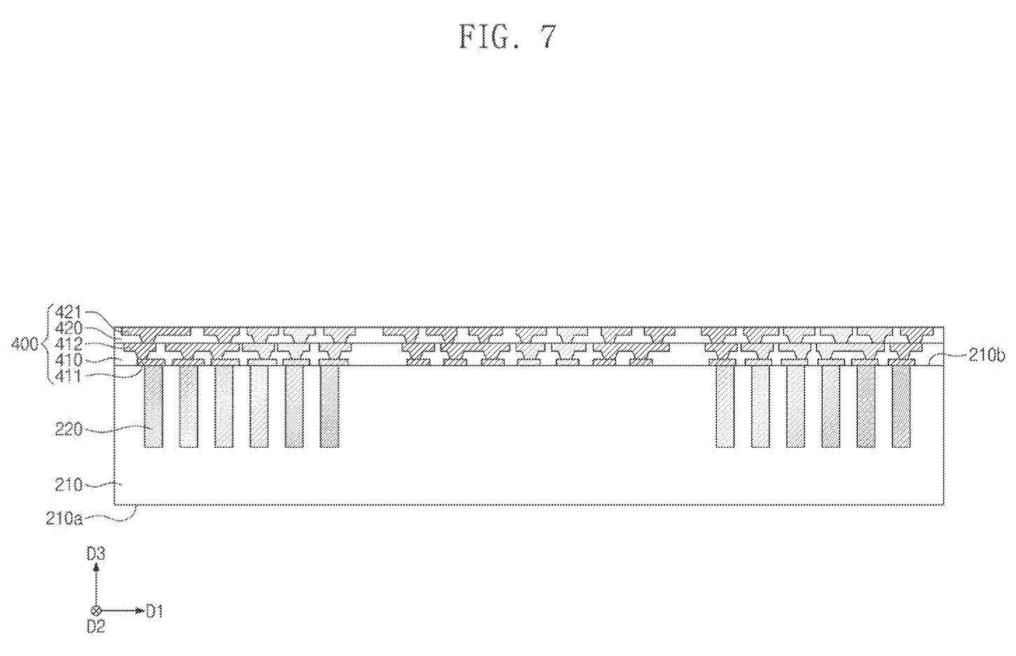

Referring to FIG. 7, inductor patterns 220 may be formed in the via holes H1. Forming the inductor patterns 220 may include conformally forming an inductor barrier pattern 221 on inner walls of the via holes H1, and filling a conductive material on the inductor barrier pattern 221 of the via holes H1 to form an inductor conductive pattern 222. The inductor barrier pattern 221 may include a metal layer/metal nitride layer.

A second package substrate 400 may be formed on the second surface 210b of the core substrate 210. Forming the second package substrate 400 may include repeating forming upper insulating patterns and upper wiring patterns. For example, forming the second package substrate 400 may include forming a first upper insulating pattern 410 on a second surface 210b of the core substrate 210, forming a first upper conductive pad 411 and a first upper wiring pattern 412 in the first upper insulating pattern 410, forming a second upper insulating pattern 420 on the first upper insulating pattern 410, and forming a second upper wiring pattern 421 in the second upper insulating pattern 420. Forming the first and second upper wiring patterns 412 and 421 may include performing a damascene process.

The first upper conductive pads 411 may be formed in the same manner as described with reference to FIG. 4A. For example, the first upper conductive pads 411 may be formed in a bar shape extending at an acute angle with each of the first direction D1 and the second direction D2.

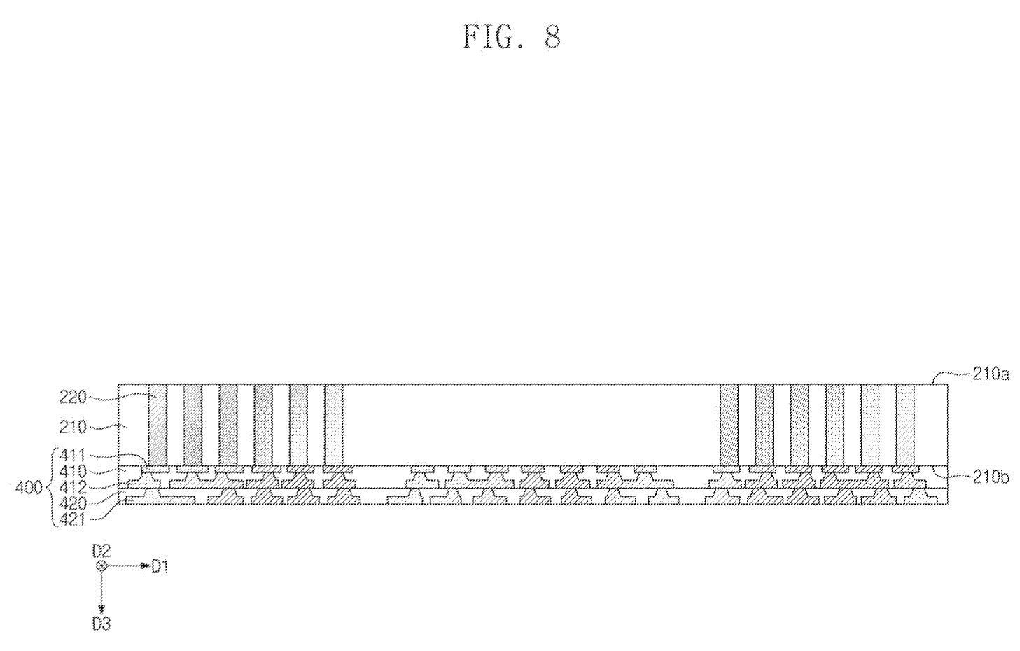

Referring to FIG. 8, the core substrate 210 may be turned over so that the first surface 210a of the core substrate 210 is exposed. The exposed first surface 210a may be etched to reduce a thickness of the core substrate 210. The etching process of the first surface 210a may be performed using an etch back or chemical mechanical polishing (CMP) process. The etching process of the first surface 210a may be performed until a bottom surface of the inductor patterns 220 is exposed.

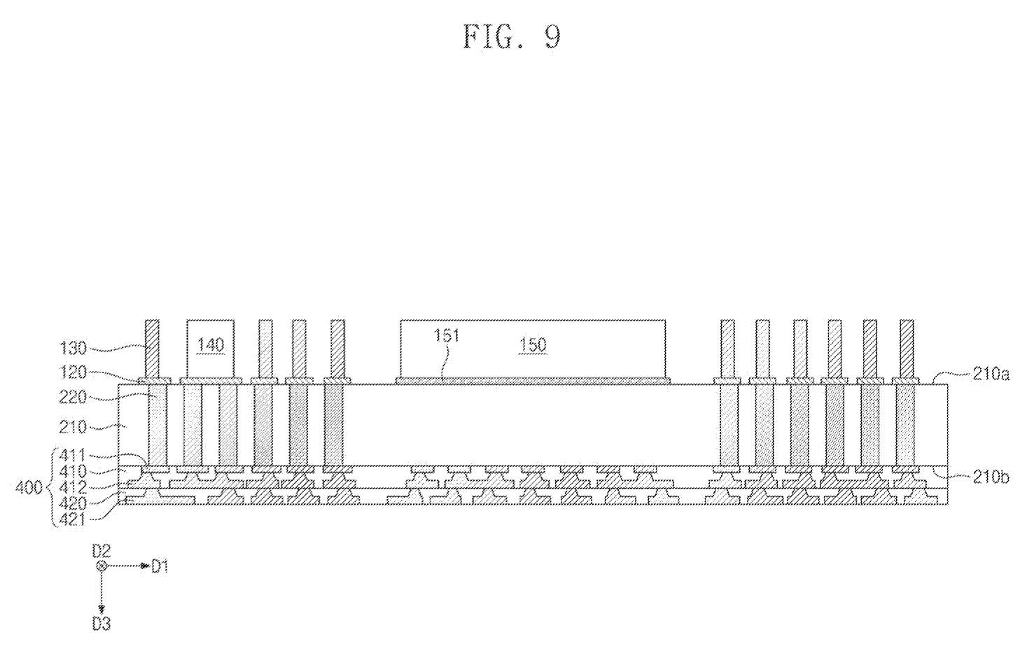

Referring to FIG. 9, conductive pads 120 may be formed on a first surface 210a of a core substrate 210. The conductive pads 120 may be formed on the bottom surface of exposed inductor patterns 220. Vertical conductive vias 130 extending vertically in the third direction D3 on the conductive pads 120 may be formed. For example, a sacrificial layer may be formed on the first surface 210a of the core substrate 210. The sacrificial layer may include, for example, a photoresist material. An etching process may be performed on the sacrificial layer to form openings exposing the first surface 210a of the core substrate 210. A conductive material may be filled in the openings to form the conductive pads 120 and the vertical conductive vias 130. Thereafter, the sacrificial layer may be removed.

The conductive pads 120 may be formed in the same manner as described with reference to FIG. 4B. For example, the conductive pads 120 may be formed in a bar shape extending in the second direction D2.

A capacitor 140 may be formed on a connection conductive pad 121 among the conductive pads 120. The connection conductive pad 121 and the capacitor 140 may be vertically overlapped. A height of the capacitor 140 may be substantially the same as or less than ae height of the vertical conductive via 130.

A first semiconductor chip 150 may be mounted on a first surface 210a of a core substrate 210. The first semiconductor chip 150 may be disposed on a central portion of the core substrate 210. To more stably mount the first semiconductor chip 150, an adhesive layer 151 may be formed between the first semiconductor chip 150 and the first surface 210a of the core substrate 210.

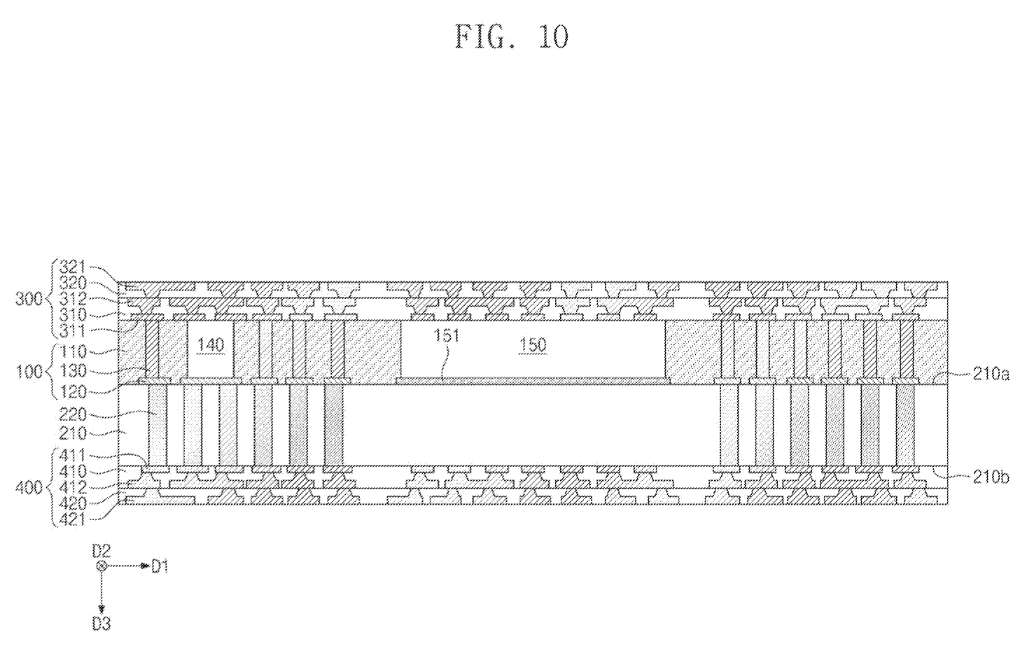

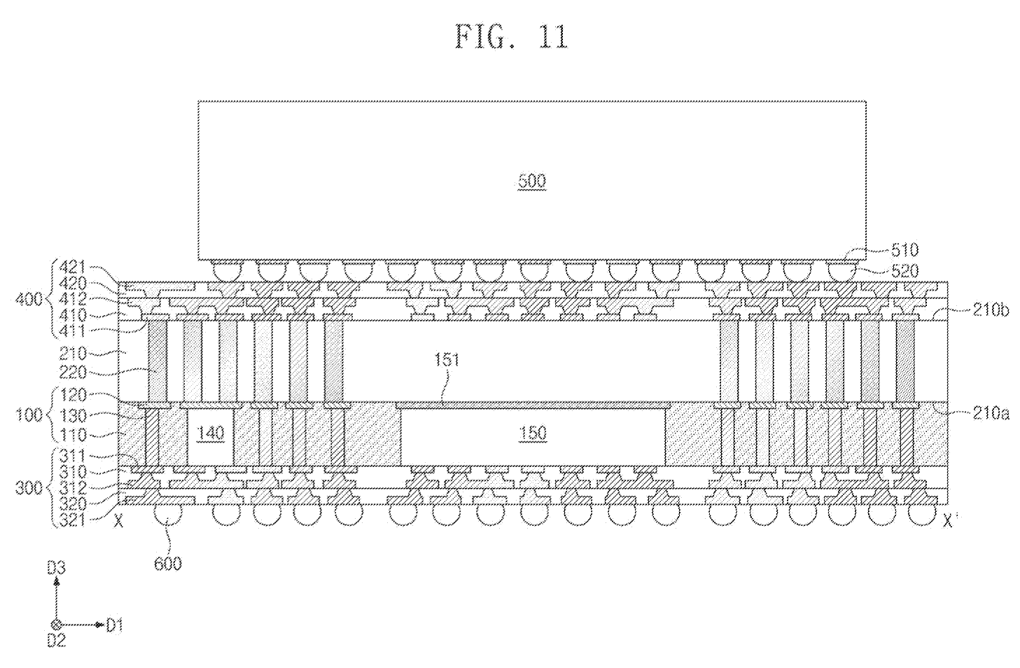

Referring to FIG. 10, a molding layer 100 may be formed by providing a first molding layer 110 on the core substrate 210. The first molding layer 110 may be provided on and cover all of the exposed surfaces of the conductive pads 120, the vertical conductive vias 130, the capacitor 140, and the first semiconductor chip 150. The first molding layer 110 may include an insulating material.

A planarization process may be performed on a top surface of the first molding layer 110. The planarization of the first molding layer 110 may include at least one of a grinding process, an etch back process, or a chemical mechanical polishing (CMP) process.

A first package substrate 300 may be formed on the molding layer 100. Forming the first package substrate 300 may be substantially the same as forming the second package substrate 400. Forming the first package substrate 300 may include repeating forming lower insulating patterns and lower wiring patterns. For example, forming the first package substrate 300 may include forming a first lower insulating pattern 310 on a molding layer 100, forming a first lower conductive pad 311 and a first lower wiring pattern 312 in the first lower insulating pattern 310, forming a second lower insulating pattern 320 on the first lower insulating pattern 310, and forming a second lower wiring pattern 321 in the second lower insulating pattern 320. Forming the first and second lower wiring patterns 312 and 321 may include performing a damascene process.

Referring to FIG. 11, external terminals 600 may be attached to a bottom surface of the first package substrate 300. The external terminals 600 may be attached to the second lower wiring patterns 321. The external terminals 600 may include solder balls or solder bumps.

After the first package substrate 300 is turned over again, a second semiconductor chip 500 may be mounted on the second package substrate 400. Then, referring to FIG. 1 again, an underfill pattern UF covering the top surface of the second package substrate 400 and the second semiconductor chip 500 may be formed to complete the semiconductor package 1.

According to one or more embodiments, the semiconductor package may be provided on the substrate, and the inductor patterns extending vertically in the core layer may constitute the inductor. The inductor patterns may be connected to the capacitor and the conductive pad to constitute the noise removal circuit. The noise removal circuit may filter the wireless signal or remove the noise from the wireless signal. In addition, the core layer may include glass, thereby minimizing frequency loss of the wireless signal. Furthermore, the heat generated from the semiconductor chip provided on the core layer may be blocked. As a result, the electrical characteristics and reliability of the semiconductor package according to embodiments may be improved.

While embodiments are described above, a person skilled in the art may understand that many modifications and variations are made without departing from the spirit and scope defined in the following claims and their equivalent. Accordingly, embodiments should be considered in all respects as illustrative and not restrictive, with the spirit and scope being indicated by the appended claims and their equivalents.

What is claimed is:

1. A semiconductor package comprising:
a first substrate;
a molding layer on the first substrate, the molding layer comprising a first semiconductor chip and a capacitor spaced apart from the first semiconductor chip in a first direction;
a core layer on the molding layer; and
a second substrate on the core layer,
wherein the second substrate comprises an upper conductive pad,
wherein the core layer comprises an inductor pattern penetrating the core layer in a third direction intersecting the first direction,
wherein the inductor pattern is connected to the capacitor by a connection conductive pad, and
wherein a top surface of the inductor pattern is in contact with the upper conductive pad.

2. The semiconductor package of claim 1, wherein the first substrate comprises a lower conductive pad, and
wherein a bottom surface of the capacitor is connected to the lower conductive pad.

3. The semiconductor package of claim 2, wherein the first semiconductor chip is an radio frequency (RF) chip, and
wherein the first semiconductor chip is connected to the lower conductive pad.

4. The semiconductor package of claim 2, wherein the molding layer further comprises a vertical conductive via extending in the third direction, and
wherein the vertical conductive via connects the inductor pattern and the lower conductive pad.

5. The semiconductor package of claim 1, wherein the core layer comprises a first inductor pattern and a second inductor pattern,
wherein the first inductor pattern and the second inductor pattern are spaced apart from each other in a second direction intersecting the first direction, and
wherein the first inductor pattern and the second inductor pattern are connected by the connection conductive pad or the upper conductive pad.

6. The semiconductor package of claim 1, wherein the core layer comprises a first inductor pattern and a second inductor pattern,
wherein the first inductor pattern and the second inductor pattern are spaced apart from each other in a second direction intersecting the first direction,
wherein the second inductor pattern is offset from the first inductor pattern in the first direction, and
wherein the first inductor pattern and the second inductor pattern are connected by one of the upper conductive pad and a conductive pad.

7. The semiconductor package of claim 1, wherein the core layer comprises a plurality of inductor patterns,
wherein the plurality of inductor patterns are connected to each other by the upper conductive pad and the connection conductive pad, and
wherein the plurality of inductor patterns, the upper conductive pad, and the connection conductive pad integrally form a coil shape.

8. The semiconductor package of claim 1, further comprising a second semiconductor chip on the second substrate,
wherein the upper conductive pad is connected to the second semiconductor chip.

9. The semiconductor package of claim 1, wherein the inductor pattern is in both sides of a central portion of the core layer,
wherein the first semiconductor chip is on the central portion of the core layer, and
wherein the semiconductor package further comprises an adhesive layer between the central portion and the first semiconductor chip.

10. The semiconductor package of claim 1, wherein the core layer comprises glass.

11. The semiconductor package of claim 1, wherein the core layer comprises a plurality of inductor patterns, and
wherein the capacitor is connected to the plurality of inductor patterns by a single connection conductive pad.

12. A semiconductor package comprising:
a first substrate comprising a lower conductive pad;
a molding layer on the first substrate, the molding layer comprising a first semiconductor chip and a capacitor spaced apart from the first semiconductor chip in a first direction;
a core layer on the molding layer; and
a second substrate on the core layer,
wherein the second substrate comprises an upper conductive pad,
wherein the core layer comprises an inductor pattern penetrating the core layer in a third direction intersecting the first direction,
wherein a top surface of the inductor pattern is in contact with the upper conductive pad, and
wherein a bottom surface of the capacitor is in contact with the lower conductive pad.

13. The semiconductor package of claim 12, wherein the core layer comprises a plurality of inductor patterns,
wherein the plurality of inductor patterns are connected to the capacitor by a connection conductive pad,
wherein the plurality of inductor patterns are connected to each other by the upper conductive pad and the connection conductive pad, and
wherein the plurality of inductor patterns, the upper conductive pad, and the connection conductive pad integrally form a coil shape.

14. The semiconductor package of claim 12, wherein the inductor pattern is in both sides of a central portion of the core layer,
wherein the first semiconductor chip is on the central portion of the core layer, and
wherein the semiconductor package further comprises an adhesive layer between the central portion and the first semiconductor chip.

15. The semiconductor package of claim 12, wherein the first semiconductor chip is an radio frequency (RF) chip, and
wherein the first semiconductor chip is connected to the lower conductive pad.

16. The semiconductor package of claim 12, wherein the molding layer further comprises a vertical conductive via extending in the third direction, and
wherein the vertical conductive via connects the inductor pattern and the lower conductive pad.

17. A semiconductor package comprising:
a first substrate;
a molding layer on the first substrate, the molding layer comprising a first semiconductor chip and a capacitor spaced apart from the first semiconductor chip in a first direction;
a core layer on the molding layer; and
a second substrate on the core layer,
wherein the second substrate comprises an upper conductive pad,
wherein the core layer comprises a plurality of inductor patterns penetrating the core layer in a third direction intersecting the first direction,
wherein the molding layer comprises a conductive pad on the plurality of inductor patterns,
wherein the conductive pad comprises a connection conductive pad interposed between at least one of the plurality of inductor patterns and the capacitor,
wherein top surfaces of the plurality of inductor patterns are connected to each other by the upper conductive pad, and
wherein the bottom surfaces of the plurality of inductor patterns are connected to each other by the conductive pad.

18. The semiconductor package of claim 17, further comprising a second semiconductor chip on the second substrate,
wherein the upper conductive pad is connected to the second semiconductor chip.

19. The semiconductor package of claim 17, wherein the core layer comprises glass.

20. The semiconductor package of claim 17, wherein the first substrate comprises a lower conductive pad, and
wherein a bottom surface of the capacitor is connected to the lower conductive pad.
